(19) United States
(12) Patent Application Publication
(10) Pub. No.: US 2025/0169124 A1
(43) Pub. Date: May 22, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiro GANGI, Marugame Kagawa (JP); Tomoaki INOKUCHI, Yokohama Kanagawa (JP); Yusuke KOBAYASHI, Yokohama Kanagawa (JP); Shotaro BABA, Kawasaki Kanagawa (JP); Hiroki NEMOTO, Meguro Tokyo (JP); Taichi FUKUDA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/735,309

(22) Filed: Jun. 6, 2024

(30) Foreign Application Priority Data
Nov. 20, 2023 (JP) 2023-196886

(51) Int. Cl. H01L 29/06; H01L 23/528; H01L 29/26; H01L 29/47

(52) U.S. Cl. CPC H10D 62/102; H01L 23/5283; H10D 62/126; H10D 62/80; H10D 64/64

(57) ABSTRACT

A semiconductor device includes a support body, a first conductive part, a second conductive part, a semiconductor layer, a third conductive part, and a fourth conductive part. The semiconductor layer includes a first end surface, a second end surface, a counter region, and a first semiconductor region. The first semiconductor region is of a first conductivity type. The first semiconductor region includes a first upper end region, a first lower end region, and a first intermediate region. The first upper end region includes a portion of the first end surface. The first lower end region includes a portion of the second end surface. A first-conductivity-type impurity concentration in the first upper end region is greater than a first-conductivity-type impurity concentration in the first intermediate region. A first-conductivity-type impurity concentration in the first lower end region is greater than the first-conductivity-type impurity concentration in the first intermediate region.

### CROSS-REFERENCE TO RELATED APPLICATIONS

This application is based upon and claims the benefit of priority from Japanese Patent Application No. 2023-196886, filed on Nov. 20, 2023; the entire contents of which are incorporated herein by reference.

### FIELD

Embodiments relate to a semiconductor device.

### BACKGROUND

It is desirable to suppress breakdown voltage degradation of a semiconductor device.

### BRIEF DESCRIPTION OF THE DRAWINGS

FIG. 1 is a schematic perspective view illustrating a semiconductor device according to an embodiment;

FIG. 2 is a schematic plan view illustrating the semiconductor device according to the embodiment;

FIG. 3 is a schematic cross-sectional view illustrating the semiconductor device according to the embodiment;

FIG. 4 is a schematic cross-sectional view illustrating the semiconductor device according to the embodiment;

FIG. 5 is a schematic cross-sectional view illustrating the semiconductor device according to the embodiment;

FIG. 6 is a schematic view illustrating an impurity concentration in the semiconductor device according to the embodiment;

FIG. 7 is a schematic perspective view illustrating a semiconductor device according to an embodiment;

FIG. 8 is a schematic plan view illustrating the semiconductor device according to the embodiment;

FIG. 9 is a schematic cross-sectional view illustrating the semiconductor device according to the embodiment;

FIG. 10 is a schematic cross-sectional view illustrating the semiconductor device according to the embodiment;

FIG. 11 is a schematic cross-sectional view illustrating a semiconductor device according to an embodiment; and

FIGS. 12A and 12B are schematic plan views illustrating semiconductor devices according to embodiments.

### DETAILED DESCRIPTION

According to one embodiment, a semiconductor device includes a support body, a first conductive part, a second conductive part, a semiconductor layer, a third conductive part, and a fourth conductive part. The support body includes a first surface. A direction from the first surface toward the first conductive part is along a first direction perpendicular to the first surface. The second conductive part is separated from the first conductive part in a second direction along the first surface. The semiconductor layer includes a first end surface, a second end surface, a counter region, and a first semiconductor region. The first end surface is positioned between the first conductive part and the second conductive part. The second end surface is positioned between the first end surface and the support body. The first semiconductor region is of a first conductivity type. The counter region is positioned between the second conductive part and the first semiconductor region and faces a portion of the second conductive part. The third conductive part is separated from the counter region and a portion of the second conductive part in a third direction. The third direction crosses the second direction and is along the first surface. The fourth conductive part is separated from the first semiconductor region in the third direction. The first semiconductor region includes a first upper end region, a first lower end region, and a first intermediate region. The first upper end region includes a portion of the first end surface. The first lower end region includes a portion of the second end surface. The first intermediate region is positioned between the first upper end region and the first lower end region. A first-conductivity-type impurity concentration in the first upper end region is greater than a first-conductivity-type impurity concentration in the first intermediate region. A first-conductivity-type impurity concentration in the first lower end region is greater than the first-conductivity-type impurity concentration in the first intermediate region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

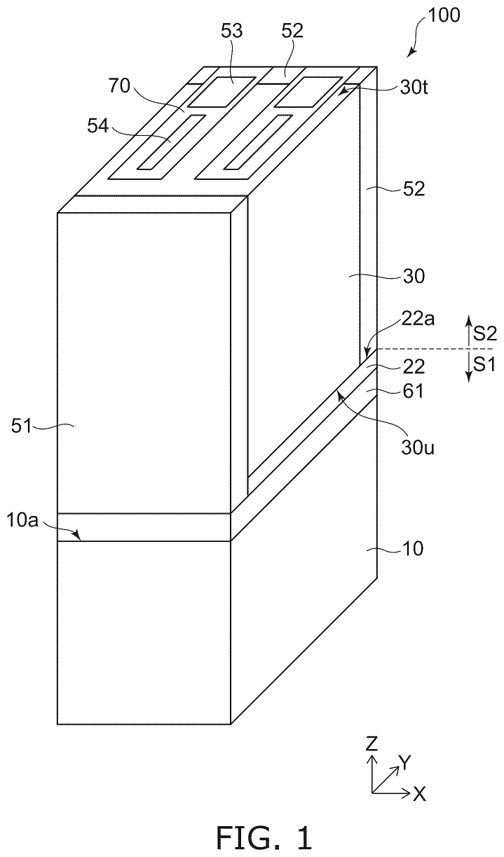

FIG. 1 is a schematic perspective view illustrating a semiconductor device according to an embodiment.

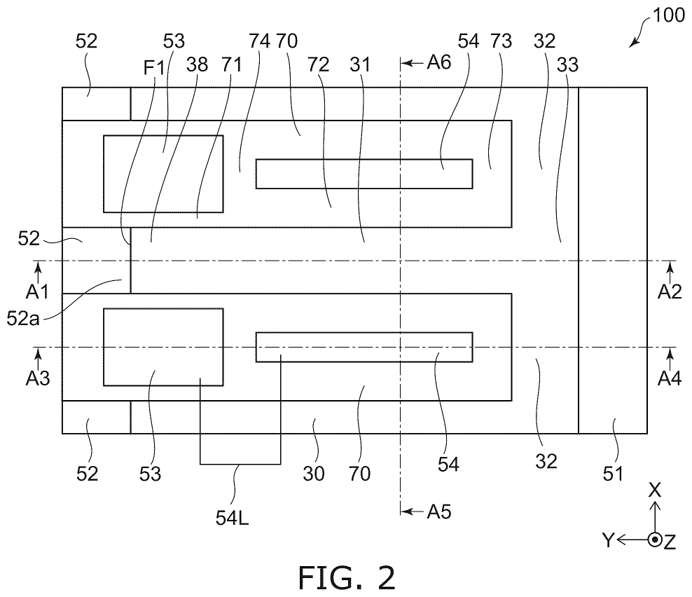

FIG. 2 is a schematic plan view illustrating the semiconductor device according to the embodiment. FIG. 2 illustrates FIG. 1 when viewed from above.

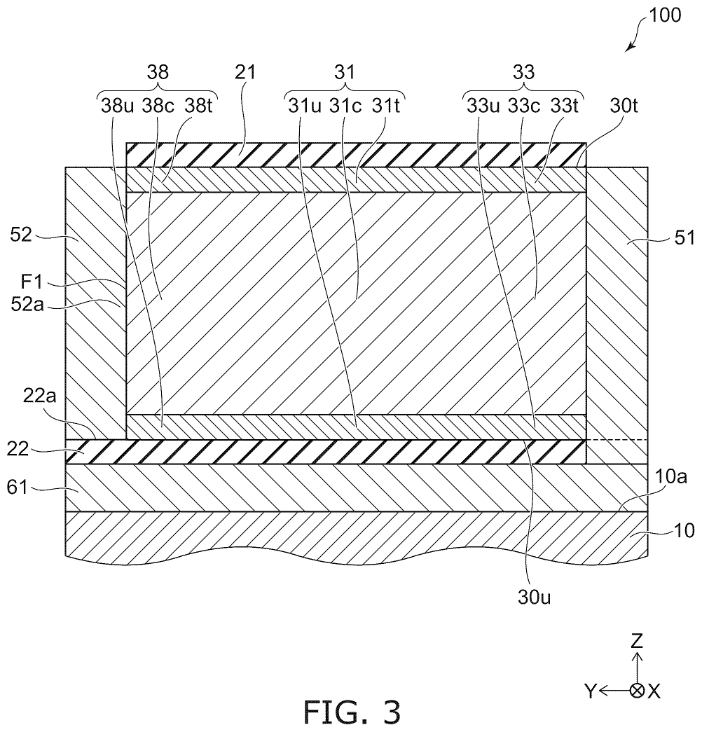

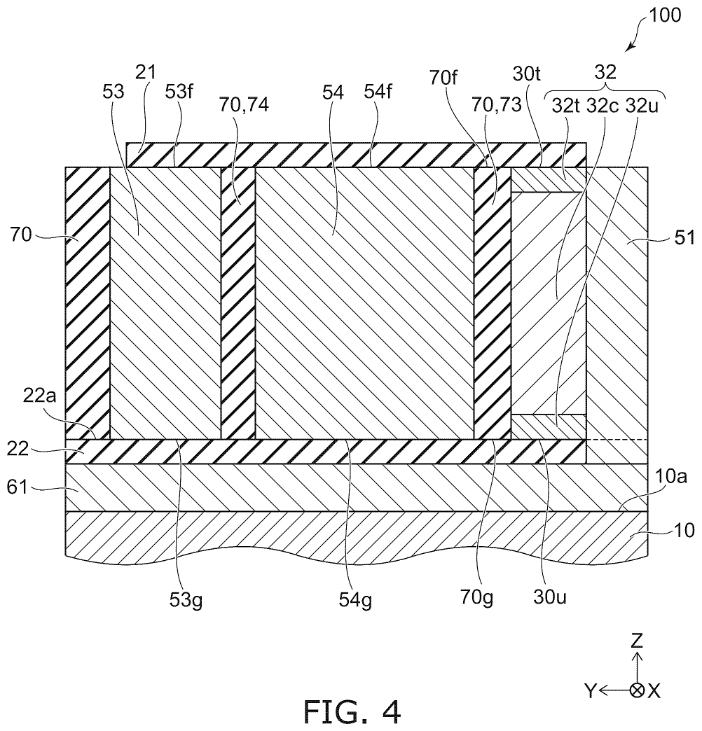

FIGS. 3 and 4 are schematic cross-sectional views illustrating the semiconductor device according to the embodiment.

FIG. 3 illustrates a cross section along line A1-A2 illustrated in FIG. 2. FIG. 4 illustrates a cross section along line A3-A4 illustrated in FIG. 2.

As illustrated in FIG. 1, the semiconductor device 100 according to the embodiment includes a support body 10, a semiconductor layer 30, a first conductive part 51, a second conductive part 52, a third conductive part 53, and a fourth conductive part 54. The semiconductor device 100 further includes an insulating part 70, a first conductive layer 61, a first insulating layer 21 (see FIG. 3), and a second insulating layer 22. The first insulating layer 21 is not illustrated for convenience in FIGS. 1 and 2.

As illustrated in FIG. 1, the support body 10 includes a first surface 10a. An element part that includes the semiconductor layer 30, the first to fourth conductive parts (51 to 54), the first conductive layer 61, the first insulating layer 21, and the second insulating layer 22 is located on the first surface 10a and supported by the support body 10. The support body 10 is, for example, a substrate.

In the description of the embodiments, a direction perpendicular to the first surface 10a is taken as a Z-direction (a first direction). One direction along the first surface 10a is taken as an X-direction. A direction that is along the first surface 10a and crosses the X-direction is taken as a Y-direction. The X-direction (the third direction) and the Y-direction (the second direction) each may be directions perpendicular to the Z-direction. The X-direction (the third direction) and the Y-direction (the second direction) may be directions orthogonal to each other. A direction perpendicular to the first surface 10a from the support body 10 toward the semiconductor layer 30 may be called “up/above”, and the opposite direction may be called “down/below”. “Up/above” and “down/below” are based on the relative positional relationship between the support body 10 and the semiconductor layer 30, and are independent of the direction of gravity.

The first conductive part 51, the second conductive part 52, and the semiconductor layer 30 are located above the first surface 10a. Specifically, the direction from the first surface 10a toward the first conductive part 51, the direction from the first surface 10a toward the second conductive part 52, and the direction from the first surface 10a toward the semiconductor layer 30 each are along the Z-direction.

The second conductive part 52 is separated from the first conductive part 51 in the Y-direction. Specifically, the direction from the first conductive part 51 toward the second conductive part 52 is along the Y-direction.

The semiconductor layer 30 is positioned between the first conductive part 51 and the second conductive part 52. Specifically, the first conductive part 51, the semiconductor layer 30, and the second conductive part 52 are arranged in the Y-direction. The semiconductor layer 30 contacts each of the first and second conductive parts 51 and 52 and is electrically connected with each of the first and second conductive parts 51 and 52. The semiconductor layer 30 includes a first end surface 30t (the upper surface) and a second end surface 30u (the lower surface). The second end surface 30u is positioned between the first end surface 30t and the support body 10.

For example, as illustrated in FIG. 2, the semiconductor layer 30 includes a counter region 38 that faces a portion 52a of the second conductive part 52. The counter region 38 includes a counter surface F1 that faces the portion 52a of the second conductive part 52. In the example, the counter region 38 is of a first conductivity type (an n-type); and the counter region 38 and the second conductive part 52 (the portion 52a) have a Schottky contact. For example, the counter surface F1 and the portion 52a of the second conductive part 52 form a Schottky junction.

As illustrated in FIG. 2, the semiconductor layer 30 includes a first semiconductor region 31, a second semiconductor region 32, and a third semiconductor region 33. The first semiconductor region 31, the second semiconductor region 32, and the third semiconductor region 33 each are of the first conductivity type.

The first semiconductor region 31 is positioned between the first conductive part 51 and the second conductive part 52. The counter region 38 is positioned between the first semiconductor region 31 and the second conductive part 52 (the portion 52a). The direction from the first semiconductor region 31 toward the counter region 38 is along the Y-direction. The first semiconductor region 31 is continuous with the counter region 38.

The second semiconductor region 32 is positioned between the first conductive part 51 and the fourth conductive part 54 in the Y-direction. The second semiconductor region 32 is electrically connected with the first conductive part 51. A portion (an insulating region 73) of the insulating part 70 is located between the second semiconductor region 32 and the fourth conductive part 54. The second semiconductor region 32 is separated from the third and fourth conductive parts 53 and 54 in the Y-direction. The direction from the second semiconductor region 32 toward the fourth conductive part 54 (or the insulating region 73) is along the Y-direction.

The third semiconductor region 33 is positioned between the first conductive part 51 and the first semiconductor region 31 in the Y-direction. The third semiconductor region 33 is electrically connected with the first conductive part 51. The third semiconductor region 33 is arranged with the first semiconductor region 31 in the Y-direction and arranged with the second semiconductor region 32 in the X-direction. In other words, the direction from the third semiconductor region 33 toward the first semiconductor region 31 is along the Y-direction; and the direction from the third semiconductor region 33 toward the second semiconductor region 32 is along the X-direction. The third semiconductor region 33 is continuous with the first and second semiconductor regions 31 and 32.

The third conductive part 53 is separated from the portion 52a of the second conductive part 52 and the counter region 38 in the X-direction. The direction from the counter region 38 (the counter surface F1) toward the third conductive part 53 is along the X-direction.

The fourth conductive part 54 is separated from the first semiconductor region 31 in the X-direction. Specifically, the direction from the first semiconductor region 31 toward the fourth conductive part 54 is along the X-direction. For example, the fourth conductive part 54 is positioned between the third conductive part 53 and the first conductive part 51 in the Y-direction.

For example, the insulating part 70 is located inside a trench provided in the semiconductor layer 30; and the third conductive part 53 and the fourth conductive part 54 are located inside the insulating part 70. The insulating part 70 insulates between the third conductive part 53 and the semiconductor layer 30, between the fourth conductive part 54 and the semiconductor layer 30, and between the third conductive part 53 and the fourth conductive part 54. More specifically, the insulating part 70 includes a first insulating region 71 located between the third conductive part 53 and the counter region 38, and a second insulating region 72 located between the fourth conductive part 54 and the first semiconductor region 31. The insulating part 70 further includes an insulating region 73 located between the fourth conductive part 54 and the second semiconductor region 32, and an insulating region 74 located between the third conductive part 53 and the fourth conductive part 54. The first insulating region 71 contacts each of the third conductive part 53 and the counter region 38. The second insulating region 72 contacts each of the fourth conductive part 54 and the first semiconductor region 31. The insulating region 73 contacts each of the fourth conductive part 54 and the second semiconductor region 32. The insulating region 74 contacts each of the third and fourth conductive parts 53 and 54.

The support body 10 can include, for example, a silicon substrate.

The semiconductor layer 30 includes, for example, at least one selected from the group consisting of silicon (Si), a nitride semiconductor (e.g., GaN, etc.), silicon carbide (SiC), and an oxide semiconductor (e.g., GaO). When a first semiconductor region 11 includes silicon, the first-conductivity-type impurity includes, for example, at least one selected from the group consisting of phosphorus, arsenic, and antimony.

The first conductive part 51 includes, for example, at least one selected from the group consisting of Al, Cu, Mo, W, Ta, Co, Ru, Ti, and Pt.

The second conductive part 52 includes, for example, at least one selected from the group consisting of Al, Cu, Mo, W, Ta, Co, Ru, Ti, and Pt. When the counter region 38 includes silicon, the portion 52a of the second conductive part 52 may include at least one selected from the group consisting of Ti, W, Mo, Ta, Zr, Al, Sn, V, Re, Os, Ir, Pt, Pd, Rh, Ru, Nb, Sr, and Hf.

The first conductive layer 61 includes, for example, at least one selected from the group consisting of Al, Cu, Mo, W, Ta, Co, Ru, Ti, and Pt.

The third conductive part 53 and the fourth conductive part 54 include, for example, at least one of polysilicon or a metal.

The first insulating layer 21 and the second insulating layer 22 are, for example, silicon oxide layers (e.g., thermal oxide films).

The insulating part 70 includes, for example, silicon oxide.

For example, the current that flows between the first conductive part 51 and the second conductive part 52 is controlled by controlling the potential of the third conductive part 53. For example, the first conductive part 51 functions as a drain electrode. For example, the second conductive part 52 functions as a source electrode. For example, the third conductive part 53 functions as a gate electrode. For example, the first insulating region 71 functions as a gate insulating film. The semiconductor device 100 is, for example, a MOSFET (metal-oxide-semiconductor field-effect transistor).

In the semiconductor device 100, a Schottky barrier is formed at the interface between the counter region 38 and the second conductive part 52. The thickness (e.g., the distance in the Y-axis direction) of the Schottky barrier can be controlled by the potential of the third conductive part 53. A current substantially does not flow when the Schottky barrier is thick. As a result, an off-state is obtained. By controlling the potential of the third conductive part 53, the Schottky barrier becomes thin, and a current (e.g., a tunnel current) flows. An on-state is obtained by the current flowing.

For example, in the on-state of the transistor, a positive voltage with respect to the second conductive part 52 is applied to the first conductive part 51; and carriers (electrons) flow from the second conductive part 52 toward the first conductive part 51 via the counter region 38, the first semiconductor region 31, and the third semiconductor region 33 (and the second semiconductor region 32).

In the example, it is sufficient for the third conductive part 53 to face the interface between the counter region 38 and the second conductive part 52 (e.g., the counter surface F1). Therefore, the gate length is short compared to, for example, a transistor of a reference example in which the gate electrode faces an n-p-n structure. As a result, the total gate charge amount (Qg) is small. The gate capacitance is small. As a result, high-speed switching is obtained. The loss is small. For example, the gate capacitance (Cg) and the gate-drain capacitance (Cgd) are reduced. The total gate charge amount (Qg) and the gate-drain charge amount (Qgd) are reduced thereby. The gate driver loss can be reduced thereby. For example, the switching can be faster. For example, the turn-on loss and the turn-off loss can be suppressed.

For example, the region that includes the counter region 38 and the second conductive part 52 (the region that includes the Schottky contact) forms a body diode. Recovery can be faster because the body diode is a Schottky barrier diode.

For example, the fourth conductive part 54 is electrically connected with the second conductive part 52. Or, the fourth conductive part 54 may be electrically connectable with the second conductive part 52. For example, the semiconductor device 100 may include a wiring part 54L that electrically connects the fourth conductive part 54 and the second conductive part 52. The fourth conductive part 54 and the second conductive part 52 may be electrically connected via wiring parts and/or terminals outside the semiconductor device 100.

The potential of the fourth conductive part 54 is set to the potential of the second conductive part 52 (e.g., a source potential). By including the fourth conductive part 54, the electric field of the semiconductor layer 30 can be controlled. For example, local electric field concentration can be suppressed. For example, high reliability is easily obtained. For example, the fourth conductive part 54 functions as a field plate.

In one example, the semiconductor device 100 can be formed by bonding the two substrates (a substrate S1 and a substrate S2) illustrated in FIG. 1. The substrate S1 is a substrate in which the first conductive layer 61 and the second insulating layer 22 are stacked on the support body 10. The substrate S2 is a substrate in which the insulating part 70 and the first to fourth conductive parts (51 to 54) are formed in the semiconductor layer 30. The substrate S1 and the substrate S2 are stacked so that the upper surface of the substrate S1 (an upper surface 22a of the second insulating layer 22) and the lower surface of the substrate S2 (the second end surface 30u) face each other. The Z-direction may be a direction perpendicular to the upper surface of the substrate S1.

As illustrated in FIG. 3, the first conductive part 51 extends along the Z-direction on the first conductive layer 61. The second conductive part 52 extends along the Z-direction on the upper surface 22a of the second insulating layer 22. As illustrated in FIG. 4, the third conductive part 53 extends along the Z-direction on the upper surface 22a of the second insulating layer 22. By such a configuration, transistors can be located at high density on the support body 10 (e.g., the substrate). The channel area per unit area can be increased. As a result, for example, the on-resistance can be reduced. A large current can be switched.

According to the embodiment, high-concentration impurity layers (in the example, high-concentration n-type layers) that have high first-conductivity-type impurity concentrations are located at the upper surface side and lower surface side of the semiconductor layer 30. The details are as follows.

As illustrated in FIG. 3, the first semiconductor region 31 includes a first lower end region 31u, a first intermediate region 31c, and a first upper end region 31t. The upper surface of the first upper end region 31t is a portion of the first end surface 30t (the upper surface) of the semiconductor layer 30. The lower surface of the first lower end region 31u is a portion of the second end surface 30u (the lower surface) of the semiconductor layer 30. The first intermediate region 31c is a region between the first upper end region 31t and the first lower end region 31u. The first intermediate region 31c is a region from the first upper end region 31t to the first lower end region 31u in the Z-direction. The first-conductivity-type impurity concentration (atoms/cm³) in the first upper end region 31t is greater than the first-conductivity-type impurity concentration (atoms/cm³) in the first intermediate region 31c. The first-conductivity-type impurity concentration (atoms/cm³) in the first lower end region 31u is greater than the first-conductivity-type impurity concentration in the first intermediate region 31c.

As illustrated in FIG. 3, the third semiconductor region 33 includes a third lower end region 33u, a third intermediate region 33c, and a third upper end region 33t. The upper surface of the third upper end region 33t is a portion of the first end surface 30t (the upper surface) of the semiconductor layer 30. The lower surface of the third lower end region 33u is a portion of the second end surface 30u (the lower surface) of the semiconductor layer 30. The third intermediate region 33c is a region between the third upper end region 33t and the third lower end region 33u. The third intermediate region 33c is a region from the third upper end region 33t to the third lower end region 33u in the Z-direction. The first-conductivity-type impurity concentration (atoms/cm³) in the third upper end region 33t is greater than the first-conductivity-type impurity concentration (atoms/cm³) in the third intermediate region 33c. The first-conductivity-type impurity concentration (atoms/cm³) in the third lower end region 33u is greater than the first-conductivity-type impurity concentration in the third intermediate region 33c.

As illustrated in FIG. 4, the second semiconductor region 32 includes a second lower end region 32u, a second intermediate region 32c, and a second upper end region 32t. The upper surface of the second upper end region 32t is a portion of the first end surface 30t (the upper surface) of the semiconductor layer 30. The lower surface of the second lower end region 32u is a portion of the second end surface 30u (the lower surface) of the semiconductor layer 30. The second intermediate region 32c is a region between the second upper end region 32t and the second lower end region 32u. The second intermediate region 32c is a region from the second upper end region 32t to the second lower end region 32u in the Z-direction. The first-conductivity-type impurity concentration (atoms/cm³) in the second upper end region 32t is greater than the first-conductivity-type impurity concentration (atoms/cm³) in the second intermediate region 32c. The first-conductivity-type impurity concentration (atoms/cm³) in the second lower end region 32u is greater than the first-conductivity-type impurity concentration in the second intermediate region 32c.

The first upper end region 31t, the second upper end region 32t, and the third upper end region 33t are continuous, and are formed as one high-concentration impurity layer. The first-conductivity-type impurity concentration in the high-concentration impurity layer is greater than the first-conductivity-type impurity concentration of the first intermediate region 31c. The first-conductivity-type impurity concentration of the first upper end region 31t may be substantially equal to the first-conductivity-type impurity concentration of the second upper end region 32t, or may be substantially equal to the first-conductivity-type impurity concentration of the third upper end region 33t. The thickness (the length along the Z-direction) of the first upper end region 31t is substantially equal to the thickness of the second upper end region 32t, or may be substantially equal to the thickness of the third upper end region 33t.

Similarly, the first lower end region 31u, the second lower end region 32u, and the third lower end region 33u are continuous, and are formed as one high-concentration impurity layer. The first-conductivity-type impurity concentration in the first lower end region 31u may be substantially equal to the first-conductivity-type impurity concentration in the second lower end region 32u, or may be substantially equal to the first-conductivity-type impurity concentration in the third lower end region 33u. The thickness of the first lower end region 31u may be substantially equal to the thickness of the second lower end region 32u, or may be substantially equal to the thickness of the third lower end region 33u.

The first intermediate region 31c, the second intermediate region 32c, and the third intermediate region 33c are continuous, and are formed as one low-concentration impurity layer. The first-conductivity-type impurity concentration in the first intermediate region 31c may be substantially equal to the first-conductivity-type impurity concentration in the second intermediate region 32c, or may be substantially equal to the first-conductivity-type impurity concentration in the third intermediate region 33c. The thickness of the first intermediate region 31c may be substantially equal to the thickness of the second intermediate region 32c, or may be substantially equal to the thickness of the third intermediate region 33c.

In the example as described above, the counter region 38 is of the first conductivity type. As illustrated in FIG. 3, the counter region 38 includes, for example, a lower counter region 38u, an intermediate counter region 38c, and an upper counter region 38t. The upper counter region 38t includes a portion of the first end surface 30t (the upper surface) of the semiconductor layer 30. The first end surface 30t is formed of the upper counter region 38t, the first upper end region 31t, the second upper end region 32t, and the third upper end region 33t. The lower counter region 38u includes a portion of the second end surface 30u (the lower surface) of the semiconductor layer 30. The second end surface 30u is formed of the lower counter region 38u, the first lower end region 31u, the second lower end region 32u, and the third lower end region 33u. The intermediate counter region 38c is between the upper counter region 38t and the lower counter region 38u.

For example, the first-conductivity-type impurity concentration (atoms/cm³) in the upper counter region 38t may be greater than the first-conductivity-type impurity concentration (atoms/cm³) in the intermediate counter region 38c. The upper counter region 38t may be a portion of the high-concentration impurity layer including the first upper end region 31t. That is, a high-concentration impurity layer may be formed over the entire upper end side of the semiconductor layer 30.

The configuration is not limited thereto; the first-conductivity-type impurity concentration in the upper counter region 38t may be equal to the first-conductivity-type impurity concentration in the intermediate counter region 38c. That is, a high-concentration impurity layer at the upper end side of the semiconductor layer 30 may be formed over the entire semiconductor layer 30 other than the counter region 38.

The first-conductivity-type impurity concentration (atoms/cm³) in the lower counter region 38u may be greater than the first-conductivity-type impurity concentration (atoms/cm³) in the intermediate counter region 38c. The lower counter region 38u may be a portion of the high-concentration impurity layer including the first lower end region 31u. That is, a high-concentration impurity layer may be formed over the entire lower end side of the semiconductor layer 30.

The configuration is not limited thereto; the first-conductivity-type impurity concentration in the lower counter region 38u may be equal to the first-conductivity-type impurity concentration in the intermediate counter region 38c. That is, the high-concentration impurity layer at the lower end side of the semiconductor layer 30 may be formed over the entire semiconductor layer 30 other than the counter region 38. When the high-concentration impurity layer is formed outside the counter region 38, for example, the effects of the high-concentration impurity layer on the threshold voltage of the transistor can be suppressed.

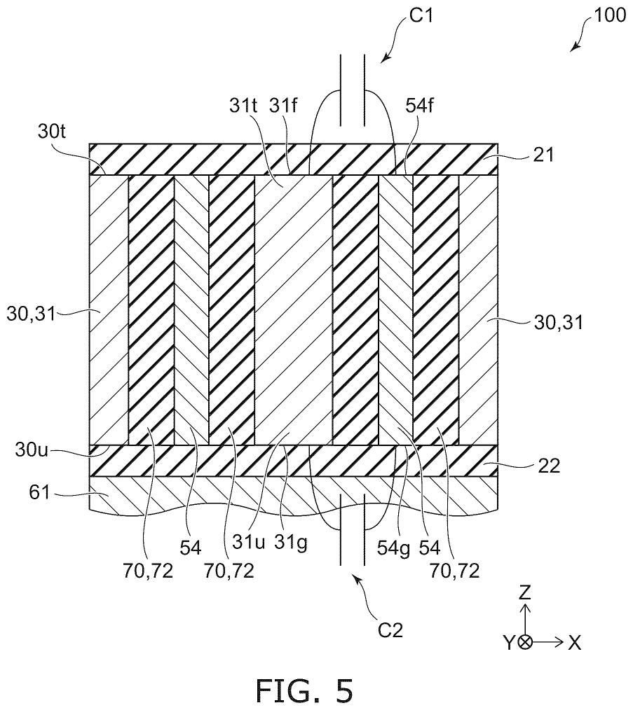

FIG. 5 is a schematic cross-sectional view illustrating the semiconductor device according to the embodiment.

FIG. 5 corresponds to a portion of a cross section along line A5-A6 shown in FIG. 2.

For example, when the first-conductivity-type impurity concentration of the entire semiconductor layer 30 is increased, the on-resistance is reduced, but the breakdown voltage may be reduced. Here, in a structure that includes a field plate, for example, charge balance of the semiconductor layer 30 is obtained to easily suppress electric field concentration. According to the impurity concentration of the semiconductor layer 30 (e.g., the first semiconductor region 31), the spreading of the depletion layer changes, and the electric field distribution is adjusted. For example, electric field concentration is suppressed by the balance between the impurity concentration and the electric field.

On the other hand, for example, as illustrated in FIG. 5, a capacitor C1 is formed between an upper end 54f (the upper surface) of the fourth conductive part 54 and an upper surface 31f of the first semiconductor region 31 (a portion of the first end surface 30t). Therefore, the upper end side of the first semiconductor region 31 is easily depleted, and there are cases where the charge balance degrades. There is a risk that the electric field may concentrate, and the breakdown voltage may be reduced. Similarly, a capacitor C2 is formed between a lower end 54g (the lower surface) of the fourth conductive part 54 and a lower surface 31g of the first semiconductor region 31 (a portion of the second end surface 30u). Therefore, the lower end side of the first semiconductor region 31 is easily depleted, and there are cases where the charge balance degrades. There is a risk that the electric field may concentrate, and the breakdown voltage may be reduced.

In contrast, according to the embodiment as described above, the first-conductivity-type impurity concentration in the first upper end region 31t is greater than the first-conductivity-type impurity concentration in the first intermediate region 31c. The first-conductivity-type impurity concentration in the first lower end region 31u is greater than the first-conductivity-type impurity concentration in the first intermediate region 31c. Depletion of the first upper end region 31t and the first lower end region 31u can be suppressed thereby. A reduction of the breakdown voltage can be suppressed. For example, the on-resistance can be reduced because the first-conductivity-type impurity concentration is high. According to the embodiment, for example, the on-resistance can be reduced without loss of the breakdown voltage.

For example, as described above, the first-conductivity-type impurity concentration in the second upper end region 32t may be greater than the first-conductivity-type impurity concentration in the second intermediate region 32c; and the first-conductivity-type impurity concentration in the second lower end region 32u may be greater than the first-conductivity-type impurity concentration in the second intermediate region 32c. The first-conductivity-type impurity concentration in the third upper end region 33t may be greater than the first-conductivity-type impurity concentration in the third intermediate region 33c; and the first-conductivity-type impurity concentration in the third lower end region 33u may be greater than the first-conductivity-type impurity concentration in the third intermediate region 33c. The reduction of the breakdown voltage can be further suppressed thereby.

As illustrated in FIG. 5, the semiconductor layer 30 (the first upper end region 31t and the first lower end region 31u) are positioned between the first insulating layer 21 and the second insulating layer 22. The first upper end region 31t is between the first lower end region 31u and the first insulating layer 21.

For example, the first insulating layer 21 contacts the first end surface 30t of the semiconductor layer 30. The first insulating layer 21 contacts the upper surface 31f of the first semiconductor region 31 (and the upper surface of the second semiconductor region 32 and the upper surface of the third semiconductor region 33). The first insulating layer 21 also contacts the upper end 54f of the fourth conductive part 54 (one end of the fourth conductive part 54 in the Z-direction). As illustrated in FIG. 4, the first insulating layer 21 also contacts an upper end 53f (the upper surface) of the third conductive part 53 and an upper end 70f (the upper surface) of the insulating part 70. The first end surface 30t, the upper end 54f, the upper end 53f, and the upper end 70f may be coplanar.

As illustrated in FIG. 5, the second insulating layer 22 contacts the second end surface 30u of the semiconductor layer 30. The second insulating layer 22 contacts the lower surface 31g of the first semiconductor region 31 (and the lower surface of the second semiconductor region 32 and the lower surface of the third semiconductor region 33). The second insulating layer 22 contacts the lower end 54g of the fourth conductive part 54 (the other end of the fourth conductive part 54 in the Z-direction). As illustrated in FIG. 4, the second insulating layer 22 also contacts a lower end 53g (the lower surface) of the third conductive part 53 and a lower end 70g (the lower surface) of the insulating part 70. The second end surface 30u, the lower end 54g, the lower end 53g, and the lower end 70g may be coplanar.

For example, the thickness (the length along the Z-direction) of the first insulating layer 21 is not less than 250 nanometers (nm) and not more than 1,250 nm. For example, the thickness (the length along the Z-direction) of the second insulating layer 22 is not less than 250 nm and not more than 1,250 nm.

There are cases where the upper end side of the semiconductor layer 30 depletes more easily due to the first insulating layer 21. There are cases where the lower end side of the semiconductor layer 30 depletes more easily due to the second insulating layer 22. In such cases as well, by providing the high-concentration impurity layers at the upper end side and lower end side of the semiconductor layer 30, depletion of the upper end side and lower end side of the semiconductor layer 30 is easily suppressed. For example, the reduction of the breakdown voltage can be suppressed thereby.

The first conductive layer 61 is electrically connected with the first conductive part 51 (see FIG. 3). For example, in the on-state of the transistor, carriers flow from the second conductive part 52 to the first conductive layer 61 via the semiconductor layer 30 and the first conductive part 51.

In the example, the first conductive layer 61 is connected below the first conductive part 51. The first conductive layer 61 extends along the X-Y plane below the semiconductor layer 30 (and the third conductive part 53, the fourth conductive part 54, and the insulating part 70). The second insulating layer 22 is located between the first conductive layer 61 and the semiconductor layer 30 (and the third conductive part 53, the fourth conductive part 54, and the insulating part 70). The first conductive layer 61 contacts the second insulating layer 22.

Thus, the first conductive layer 61 is below the semiconductor layer 30 and the second insulating layer 22. In other words, the first lower end region 31u is between the first upper end region 31t and the first conductive layer 61. In other words, the second end surface 30u is between the first end surface 30t and the first conductive layer 61.

The configuration is not limited thereto; according to the embodiment, the first conductive layer 61 (the drain) may be located above the semiconductor layer 30 and the first insulating layer 21. In other words, the first upper end region 31t may be between the first lower end region 31u and the first conductive layer 61.

The first-conductivity-type impurity concentration in one of the first upper end region 31t or the first lower end region 31u may be greater than the first-conductivity-type impurity concentration in the other of the first upper end region 31t or the first lower end region 31u. Depletion in the one of the first upper end region 31t or the first lower end region 31u can be further suppressed thereby. For example, the first conductive layer 61 (the drain) is located at the other of the first upper end region 31t or the first lower end region 31u. In other words, the other of the first upper end region 31t or the first lower end region 31u is between the first conductive layer 61 and the one of the first upper end region 31t or the first lower end region 31u. Here, a voltage that is different from that of the second conductive part 52 is applied to the first conductive part 51 and the first conductive layer 61 when operating the semiconductor device 100. Therefore, there are cases where the end portion (the one of the first upper end region 31t or the first lower end region 31u) of the semiconductor layer 30 at the side opposite to the first conductive layer 61 is depleted more easily than the end portion (the other of the first upper end region 31t or the first lower end region 31u) of the semiconductor layer 30 at the first conductive layer 61 side.

In contrast, for example, the first-conductivity-type impurity concentration of the end portion (the one of the first upper end region 31t or the first lower end region 31u) of the semiconductor layer 30 at the side opposite to the first conductive layer 61 is greater than the first-conductivity-type impurity concentration of the end portion (the other of the first upper end region 31t or the first lower end region 31u) of the semiconductor layer 30 at the first conductive layer 61 side. For example, depletion at the end portion of the semiconductor layer 30 at the side opposite to the first conductive layer 61 can be further suppressed thereby. However, according to the embodiment, the first-conductivity-type impurity concentration of the end portion of the semiconductor layer 30 at the first conductive layer 61 side may be greater than the first-conductivity-type impurity concentration of the end portion of the semiconductor layer 30 at the side opposite to the first conductive layer 61.

For example, when the first insulating layer 21 is thick, there are cases where the upper end side (the first upper end region 31t) of the semiconductor layer 30 is more easily depleted. For example, when the second insulating layer 22 is thick, there are cases where the lower end side (the first lower end region 31u) of the semiconductor layer 30 is more easily depleted.

The thickness of one of the first insulating layer 21 or the second insulating layer 22 may be less than the thickness of the other of the first insulating layer 21 or the second insulating layer 22. For example, depletion of the semiconductor layer 30 at the one of the first insulating layer 21 or the second insulating layer 22 can be further suppressed thereby. For example, the first conductive layer 61 (the drain) is located at the other of the first insulating layer or the second insulating layer. In other words, the other of the first insulating layer 21 or the second insulating layer 22 is positioned between the first conductive layer 61 and the one of the first insulating layer 21 or the second insulating layer 22. Here, as described above, there are cases where the end portion of the semiconductor layer 30 at the side opposite to the first conductive layer 61 is relatively easily depleted.

Therefore, for example, the insulating layer at the side opposite to the first conductive layer 61 (the one of the first insulating layer 21 or the second insulating layer 22) may be thinner than the insulating layer at the first conductive layer 61 side (the other of the first insulating layer 21 or the second insulating layer 22). In other words, in the example of FIG. 5, the thickness of the first insulating layer 21 may be less than the thickness of the second insulating layer 22. For example, depletion at the end portion of the semiconductor layer 30 at the side opposite to the first conductive layer 61 can be further suppressed thereby. However, according to the embodiment, the insulating layer at the first conductive layer 61 side may be thinner than the insulating layer at the side opposite to the first conductive layer 61.

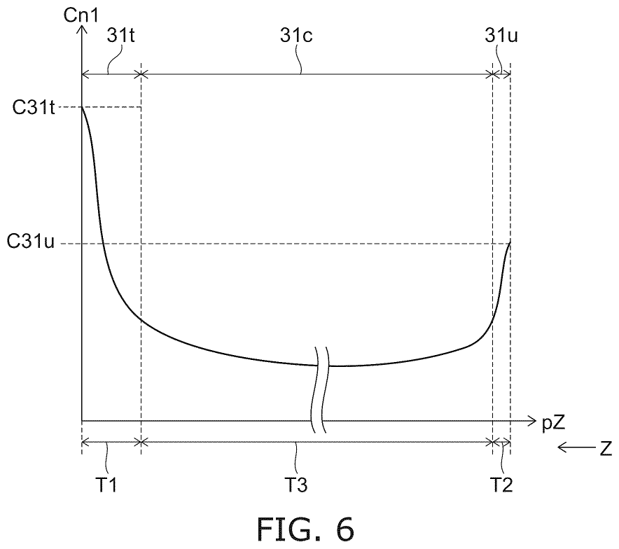

FIG. 6 is a schematic view illustrating the impurity concentration in the semiconductor device according to the embodiment.

FIG. 6 is a schematic graph illustrating an example of the first-conductivity-type impurity concentration distribution along the Z-direction of the semiconductor layer 30. The vertical axis is a first-conductivity-type impurity concentration Cn1 in the first semiconductor region 31. The horizontal axis is a position pZ in the Z-direction.

A thickness T1 (the length along the Z-direction) of the first upper end region 31t is, for example, not less than 100 nm and not more than 1,000 nm, e.g., 500 nm. A thickness T2 (the length along the Z-direction) of the first lower end region 31u is, for example, not less than 100 nm and not more than 1,000 nm, e.g., 500 nm. A thickness T3 of the first intermediate region 31c (i.e., the distance along the Z-direction between the first upper end region 31t and the first lower end region 31u) is, for example, not less than 3,000 nm and not more than 60,000 nm. The thickness T1 is less than the thickness T3. The thickness T2 is less than the thickness T3. As a result, for example, the on-resistance can be reduced without loss of the breakdown voltage.

The first-conductivity-type impurity concentration of the first upper end region 31t may be different from the first-conductivity-type impurity concentration of the first lower end region 31u. The first-conductivity-type impurity concentration distribution along the Z-direction in the first upper end region 31t has a maximum concentration C31t (e.g., a peak concentration). The first-conductivity-type impurity concentration distribution along the Z-direction in the first lower end region 31u has a maximum concentration C31u (e.g., a peak concentration). The maximum concentration C31t may be different from the maximum concentration C31u.

In the example as described above, the first conductive layer 61 is located below the first lower end region 31u. The first upper end region 31t has a higher first-conductivity-type impurity concentration than the first lower end region 31u. For example, in the first-conductivity-type impurity concentration distribution along the Z-direction, the maximum concentration C31t of the first upper end region 31t is greater than the maximum concentration C31u of the first lower end region 31u.

The configuration is not limited thereto; the first-conductivity-type impurity concentration in the first upper end region 31t may be equal to the first-conductivity-type impurity concentration in the first lower end region 31u, or may be less than the first-conductivity-type impurity concentration in the first lower end region 31u. For example, the maximum concentration C31t may be less than the maximum concentration C31u.

For example, the first-conductivity-type impurity amount (the total amount (the number of atoms) of the impurity) included in the first upper end region 31t is greater than the first-conductivity-type impurity amount included in the first intermediate region 31c. For example, the first-conductivity-type impurity amount (atoms/cm²) per unit area of the first upper end region 31t is greater than the first-conductivity-type impurity amount per unit area of the first intermediate region 31c. Per unit area refers to per unit area in a plane perpendicular to the Z-direction. For example, the difference between the first-conductivity-type impurity amount included in the first upper end region 31t and the first-conductivity-type impurity amount included in the first intermediate region 31c is not less than 5×10¹⁰ atoms/cm² and not more than 1.5×10¹¹ atoms/cm² per unit area in a plane perpendicular to the Z-direction. By setting the first-conductivity-type impurity amount in the first upper end region 31t to be high, depletion can be suppressed, and the reduction of the breakdown voltage can be suppressed.

This is similar for the second and third semiconductor regions 32 and 33. In other words, for example, the first-conductivity-type impurity amount included in the second upper end region 32t is greater than the first-conductivity-type impurity amount included in the second intermediate region 32c. For example, the first-conductivity-type impurity amount included in the third upper end region 33t is greater than the first-conductivity-type impurity amount included in the third intermediate region 33c.

For example, the first-conductivity-type impurity amount included in the first lower end region 31u also is greater than the first-conductivity-type impurity amount included in the first intermediate region 31c. For example, the first-conductivity-type impurity amount (atoms/cm²) per unit area of the first lower end region 31u is greater than the first-conductivity-type impurity amount per unit area of the first intermediate region 31c. For example, the difference between the first-conductivity-type impurity amount included in the first lower end region 31u and the first-conductivity-type impurity amount included in the first intermediate region 31c is not less than 5×10¹⁰ atoms/cm² and not more than 1.5×10¹¹ atoms/cm² per unit area in a plane perpendicular to the Z-direction. By setting the first-conductivity-type impurity amount in the first lower end region 31u to be high, depletion can be suppressed, and the reduction of the breakdown voltage can be suppressed.

This is similar for the second and third semiconductor regions 32 and 33. In other words, for example, the first-conductivity-type impurity amount included in the second lower end region 32u is greater than the first-conductivity-type impurity amount included in the second intermediate region 32c. For example, the first-conductivity-type impurity amount included in the third lower end region 33u is greater than the first-conductivity-type impurity amount included in the third intermediate region 33c.

The first-conductivity-type impurity concentration in the first upper end region 31t is, for example, not less than 1.3×10¹⁶ atoms/cm³ and not more than 6.5×10¹⁶ atoms/cm³. The first-conductivity-type impurity concentration in the first lower end region 31u is, for example, not less than 1.3×10¹⁶ atoms/cm³ and not more than 6.5×10¹⁶ atoms/cm³. The first-conductivity-type impurity concentration in the first intermediate region 31c is, for example, not less than 1×10¹⁶ atoms/cm³ and not more than 5×10¹⁶ atoms/cm³.

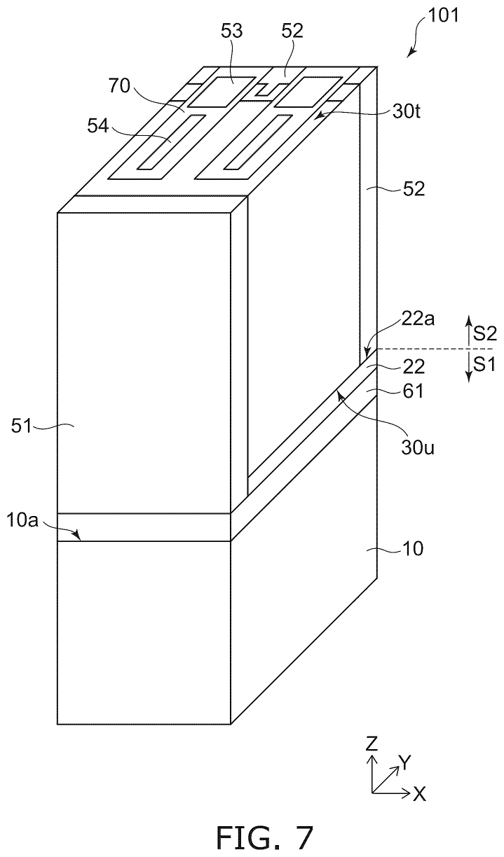

FIG. 7 is a schematic perspective view illustrating a semiconductor device according to an embodiment.

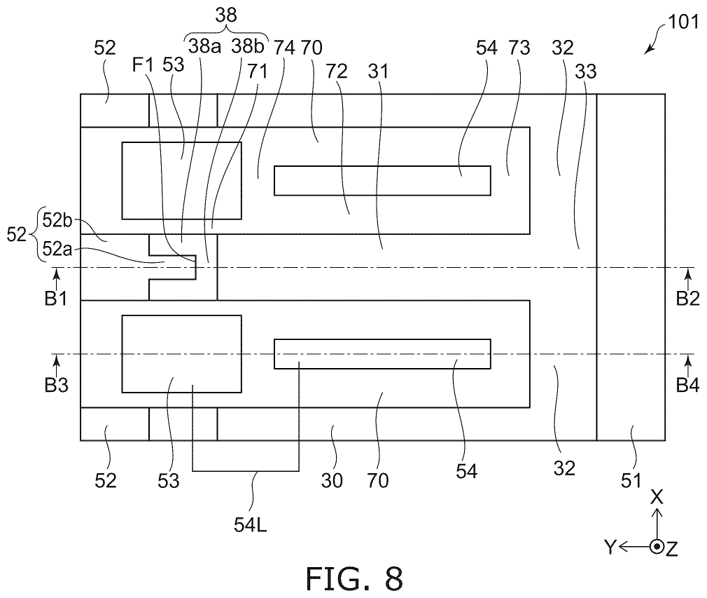

FIG. 8 is a schematic plan view illustrating the semiconductor device according to the embodiment. FIG. 8 illustrates FIG. 7 when viewed from above.

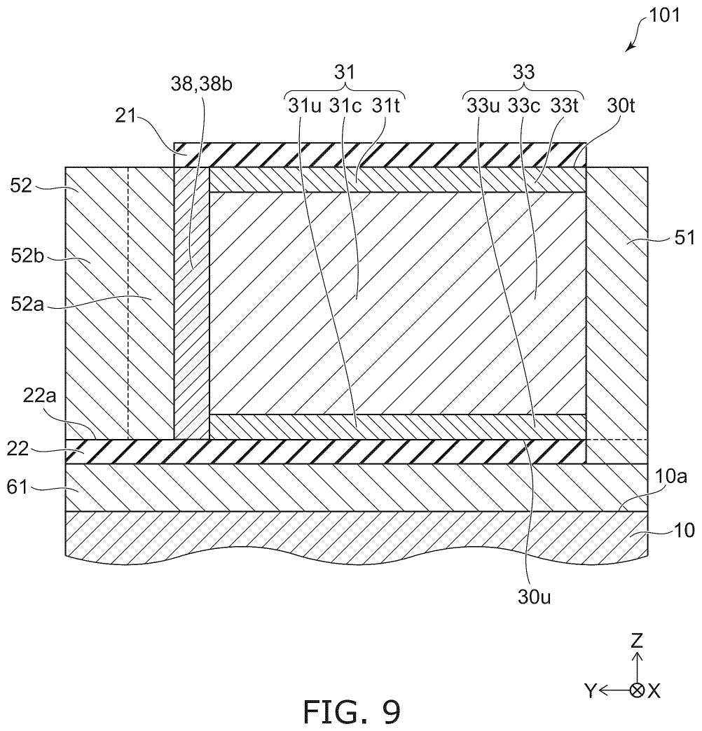

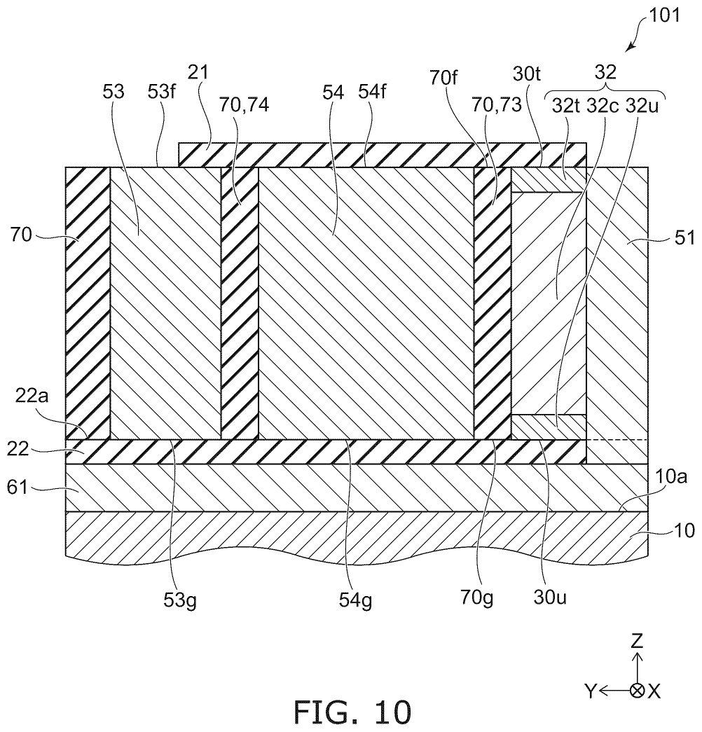

FIGS. 9 and 10 are schematic cross-sectional views illustrating the semiconductor device according to the embodiment.

FIG. 9 illustrates a cross section along line B1-B2 illustrated in FIG. 8. FIG. 10 illustrates a cross section along line B3-B4 illustrated in FIG. 8.

In the semiconductor device 101 illustrated in FIGS. 7 to 10, the counter region 38 of the semiconductor layer 30 is of a second conductivity type (a p-type). As illustrated in FIG. 8, the portion 52a of the second conductive part 52 has a shape that protrudes from a portion 52b of the second conductive part 52 toward the first conductive part 51.

The counter region 38 includes a first part 38a and a second part 38b. The first part 38a is positioned between the third conductive part 53 and the portion 52a of the second conductive part 52 in the X-direction. The second part 38b is positioned between the first part 38a and the first semiconductor region 31 and between the first semiconductor region 31 and the portion 52a of the second conductive part 52 in the Y-direction. The first part 38a and the second part 38b contact the portion 52a of the second conductive part 52. The first insulating region 71 is located between the first part 38a and the third conductive part 53 and between the second part 38b and the third conductive part 53.

The first semiconductor region 31 and the second part 38b of the counter region 38 form a p-n junction. The direction from the p-n junction toward the third conductive part 53 is along the Y-direction. For example, boron can be used as a second-conductivity-type impurity.

Otherwise, a description similar to that of the configuration of the semiconductor device 100 is applicable to the configuration of the semiconductor device 101.

The semiconductor device 101 is, for example, a p-n-type transistor. The height of the barrier formed between the counter region 38 and the first semiconductor region 31 can be controlled by the potential of the third conductive part 53. By controlling the potential of the third conductive part 53, an off-state is obtained in which a current substantially does not flow between the first conductive part 51 and the second conductive part 52. By controlling the potential of the third conductive part 53, an on-state is obtained in which carriers flow from the second conductive part 52 toward the first conductive part 51 via the semiconductor layer 30. When the counter region 38 is of the second conductivity type, for example, effects of the high-concentration impurity layer (the first upper end region 31t and the first lower end region 31u) on the threshold voltage of the transistor can be suppressed.

In the semiconductor device 101 as well, similarly to the semiconductor device 100, the reduction of the breakdown voltage can be suppressed. For example, the on-resistance can be reduced without loss of the breakdown voltage.

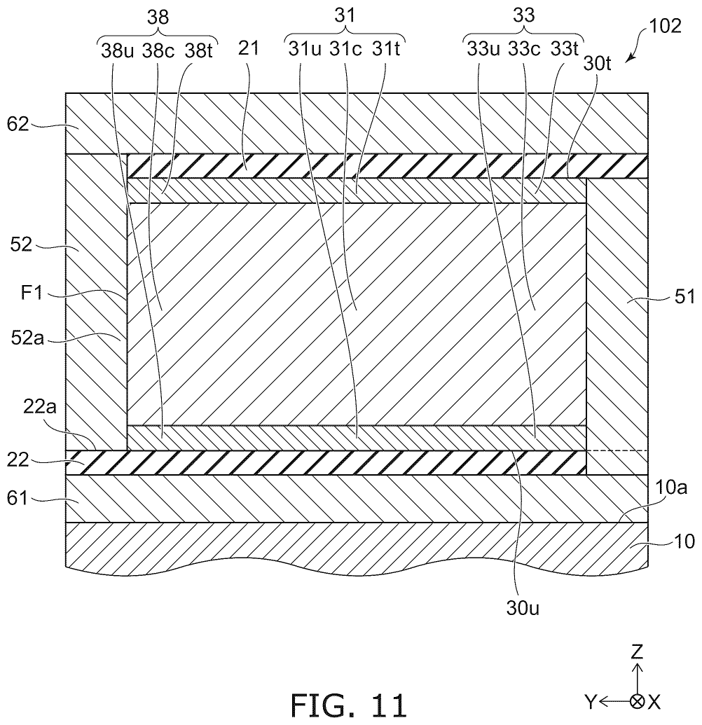

FIG. 11 is a schematic cross-sectional view illustrating a semiconductor device according to an embodiment.

The semiconductor device 102 according to the embodiment illustrated in FIG. 11 includes a second conductive layer 62. Otherwise, a description similar to that of the configuration of the semiconductor device 100 is applicable to the configuration of the semiconductor device 102. Similarly to the cross section of the semiconductor device 100 illustrated in FIG. 3, FIG. 11 illustrates the cross section of the semiconductor device 102.

The second conductive layer 62 is electrically connected with the second conductive part 52. For example, in the on-state of the transistor, carriers flow from the second conductive layer 62 to the first conductive layer 61 via the second conductive part 52, the semiconductor layer 30, and the first conductive part 51.

The second conductive layer 62 is located at the side of the semiconductor layer 30 opposite to the first conductive layer 61. In other words, the semiconductor layer 30 is positioned between the first conductive layer 61 and the second conductive layer 62. In the example, the second conductive layer 62 is positioned above the semiconductor layer 30; and the first conductive layer 61 is positioned below the semiconductor layer 30. In other words, the first upper end region 31t is between the second conductive layer 62 and the first lower end region 31u. Similarly, the second upper end region 32t is between the second conductive layer 62 and the second lower end region 32u; and the third upper end region 33t is between the second conductive layer 62 and the third lower end region 33u. The second conductive layer 62 may be positioned above the first insulating layer 21 and may contact the first insulating layer 21.

In the semiconductor device 102 as well, similarly to the semiconductor device 100, the reduction of the breakdown voltage can be suppressed. For example, the on-resistance can be reduced without loss of the breakdown voltage.

For example, in the semiconductor device 102, the first-conductivity-type impurity concentration in the first upper end region 31t may be greater than the first-conductivity-type impurity concentration in the first lower end region 31u. For example, in the semiconductor device 102, the first insulating layer 21 may be thinner than the second insulating layer 22. As a result, for example, depletion of the semiconductor layer 30 at the source side (the side opposite to the drain) can be suppressed.

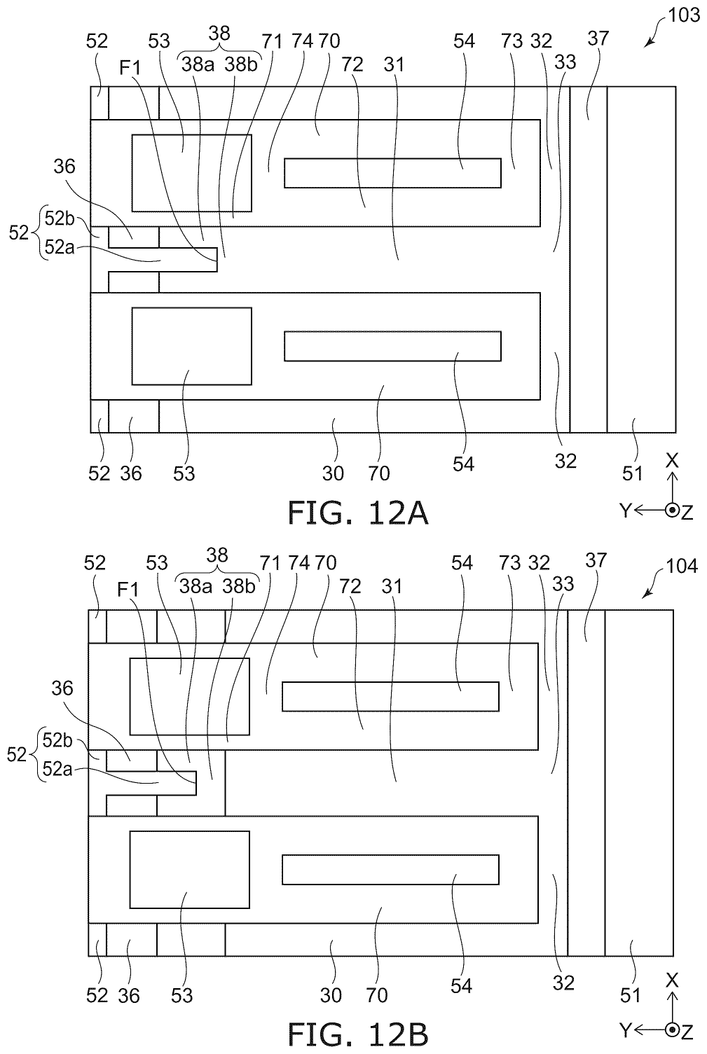

FIGS. 12A and 12B are schematic plan views illustrating semiconductor devices according to embodiments.

In a semiconductor device 103 according to the embodiment illustrated in FIG. 12A, the semiconductor layer 30 includes a source region 36 and a drain region 37. The portion 52a of the second conductive part 52 has a shape that protrudes from the portion 52b of the second conductive part 52 toward the first conductive part 51. Otherwise, a description similar to that of the configuration of the semiconductor device 100 is applicable to the configuration of the semiconductor device 103. Similarly to the plan view of the semiconductor device 100 illustrated in FIG. 2, FIG. 12A is a plan view of the semiconductor device 103.

In the semiconductor device 103, the counter region 38 is of the first conductivity type, and includes the first part 38a and the second part 38b. The first part 38a and the second part 38b have Schottky contacts with the portion 52a of the second conductive part 52.

The source region 36 is positioned between the second conductive part 52 (the portion 52b) and the counter region 38 in the Y-direction. The source region 36 is positioned between the second conductive part 52 (the portion 52a) and the third conductive part 53 in the X-direction. The source region 36 is of the first conductivity type. In the semiconductor device 103, the first-conductivity-type impurity concentration in the source region 36 is greater than the first-conductivity-type impurity concentration in the counter region 38. By including the source region 36, a good electrical connection is obtained between the second conductive part 52 and the semiconductor layer 30. For example, the on-resistance can be reduced.

The drain region 37 is located between the second semiconductor region 32 and the first conductive part 51 and between the third semiconductor region 33 and the first conductive part 51. The drain region 37 is of the first conductivity type. The first-conductivity-type impurity concentration in the drain region 37 is greater than the first-conductivity-type impurity concentration in the first semiconductor region 31 (e.g., the first intermediate region 31c or the first upper end region 31t). By including the drain region 37, a good electrical connection is obtained between the first conductive part 51 and the semiconductor layer 30.

In a semiconductor device 104 according to the embodiment illustrated in FIG. 12B as well, the semiconductor layer 30 includes the source region 36 and the drain region 37. Otherwise, a description similar to that of the configuration of the semiconductor device 101 is applicable to the configuration of the semiconductor device 104. Similarly to the plan view of the semiconductor device 101 illustrated in FIG. 8, FIG. 12B is a plan view of the semiconductor device 104. The semiconductor device 104 is, for example, an n-p-n-type transistor.

Thus, at least one of the source region 36 or the drain region 37 may be included as appropriate in the semiconductor devices according to the embodiments.

The embodiments may include the following configurations (for example, technical proposals).

### Configuration 1

A semiconductor device, comprising:
a support body including a first surface;
a first conductive part, a direction from the first surface toward the first conductive part being along a first direction perpendicular to the first surface;
a second conductive part separated from the first conductive part in a second direction along the first surface;
a semiconductor layer including a first end surface, a second end surface, a counter region, and a first semiconductor region, the first end surface being positioned between the first conductive part and the second conductive part, the second end surface being positioned between the first end surface and the support body, the first semiconductor region being of a first conductivity type, the counter region being positioned between the second conductive part and the first semiconductor region and facing a portion of the second conductive part;
a third conductive part separated from the counter region and a portion of the second conductive part in a third direction, the third direction crossing the second direction and being along the first surface; and
a fourth conductive part separated from the first semiconductor region in the third direction,
the first semiconductor region including
   a first upper end region including a portion of the first end surface,
   a first lower end region including a portion of the second end surface, and
   a first intermediate region positioned between the first upper end region and the first lower end region,
a first-conductivity-type impurity concentration in the first upper end region being greater than a first-conductivity-type
impurity concentration in the first intermediate region, a first-conductivity-type impurity concentration in the first lower end region being greater than the first-conductivity-type impurity concentration in the first intermediate region.

### Configuration 2

The device according to configuration 1, wherein
the counter region is of the first conductivity type and has a Schottky contact with the portion of the second conductive part.

### Configuration 3

The device according to configuration 1, wherein
the counter region is of a second conductivity type.

### Configuration 4

The device according to any one of configurations 1 to 3, further comprising:
a first insulating layer contacting the first end surface, and
a second insulating layer contacting the second end surface.

### Configuration 5

The device according to configuration 4, wherein
the first insulating layer contacts one end in the first direction of the fourth conductive part, and
the second insulating layer contacts another end in the first direction of the fourth conductive part.

### Configuration 6

The device according to configuration 4 or 5, wherein
a thickness of the first insulating layer is not less than 250 nm and not more than 1,250 nm, and
a thickness of the second insulating layer is not less than 250 nm and not more than 1,250 nm.

### Configuration 7

The device according to any one of configurations 1 to 6, wherein
the first-conductivity-type impurity concentration in one of the first upper end region or the first lower end region is greater than the first-conductivity-type impurity concentration in the other of the first upper end region or the first lower end region.

### Configuration 8

The device according to configuration 7, further comprising:
a first conductive layer electrically connected with the first conductive part,
the other of the first upper end region or the first lower end region being positioned between the first conductive layer and the one of the first upper end region or the first lower end region.

### Configuration 9

The device according to any one of configurations 4 to 6, wherein
the first lower end region is positioned between the first insulating layer and the second insulating layer,
the first upper end region is positioned between the first lower end region and the first insulating layer, and
a thickness of one of the first insulating layer or the second insulating layer is less than a thickness of the other of the first insulating layer or the second insulating layer.

### Configuration 10

The device according to configuration 9, further comprising:
a first conductive layer electrically connected with the first conductive part,
the other of the first insulating layer or the second insulating layer being positioned between the first conductive layer and the one of the first insulating layer or the second insulating layer.

### Configuration 11

The device according to configuration 8 or 10, wherein
the second end surface is positioned between the first end surface and the first conductive layer.

### Configuration 12

The device according to configuration 8, 10, or 11, further comprising:
a second conductive layer electrically connected with the second conductive part,
the semiconductor layer being positioned between the first conductive layer and the second conductive layer.

### Configuration 13

The device according to any one of configurations 1 to 12, wherein
the semiconductor layer includes a second semiconductor region separated from the fourth conductive part in the second direction and positioned between the fourth conductive part and the first conductive part, the second semiconductor region being of the first conductivity type,
the second semiconductor region includes
   a second upper end region including a portion of the first end surface,
   a second lower end region including a portion of the second end surface, and
   a second intermediate region positioned between the second upper end region and the second lower end region,
a first-conductivity-type impurity concentration in the second upper end region is greater than a first-conductivity-type impurity concentration in the second intermediate region, and
a first-conductivity-type impurity concentration in the second lower end region is greater than the first-conductivity-type impurity concentration in the second intermediate region.

### Configuration 14

The device according to configuration 13, wherein
the semiconductor layer includes a third semiconductor region positioned between the first semiconductor region and the first conductive part in the second direction, the third semiconductor region being of the first conductivity type,
a direction from the second semiconductor region toward the third semiconductor region is along the third direction,
the third semiconductor region includes
   a third upper end region including a portion of the first end surface,
   a third lower end region including a portion of the second end surface, and
   a third intermediate region positioned between the third upper end region and the third lower end region,
a first-conductivity-type impurity concentration in the third upper end region is greater than a first-conductivity-type impurity concentration in the third intermediate region, and
a first-conductivity-type impurity concentration in the third lower end region is greater than the first-conductivity-type impurity concentration in the third intermediate region.

### Configuration 15

The device according to any one of configurations 1 to 14, wherein
the fourth conductive part is electrically connected with the second conductive part.

### Configuration 16

The device according to any one of configurations 1 to 15 wherein
a thickness of the first upper end region is not less than 100 nm and not more than 1,000 nm,
a thickness of the first lower end region is not less than 100 nm and not more than 1,000 nm,
the thickness of the first upper end region is less than a thickness of the first intermediate region, and
the thickness of the first lower end region is less than the thickness of the first intermediate region.

### Configuration 17

The device according to configuration 16, wherein
a first-conductivity-type impurity amount included in the first upper end region is greater than a first-conductivity-type impurity amount included in the first intermediate region.

### Configuration 18

The device according to configuration 17, wherein
a difference between the first-conductivity-type impurity amount included in the first upper end region and the first-conductivity-type impurity amount included in the first intermediate region is not less than 5×10¹⁰ atoms/cm² and not more than 1.5×10¹¹ atoms/cm² per unit area in a plane perpendicular to the first direction.

### Configuration 19

The device according to any one of configurations 1 to 18, wherein
the first-conductivity-type impurity concentration in the first intermediate region is not less than 1×10¹⁶ atoms/cm³ and not more than 5×10¹⁶ atoms/cm³, and
the first-conductivity-type impurity concentration in the first upper end region is not less than 1.3×10¹⁶ atoms/cm³ and not more than 6.5×10¹⁶ atoms/cm³.

### Configuration 20

The device according to any one of configurations 1 to 19, further comprising:
an insulating part including
   a first insulating region located between the third conductive part and the counter region, and
   a second insulating region located between the fourth conductive part and the first semiconductor region.

Information that relates to the configurations of the semiconductor regions, etc., in the embodiments is obtained by, for example, electron microscopy, etc. Information that relates to the impurity concentrations of the materials and semiconductor regions is obtained by, for example, EDX (Energy Dispersive X-ray Spectroscopy), SIMS (Secondary Ion Mass Spectrometry), etc. Information that relates to the carrier concentration in the semiconductor regions is obtained by, for example, SCM (Scanning Capacitance Microscopy), etc.

According to embodiments, a semiconductor device can be provided in which a reduction of the breakdown voltage can be suppressed.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes Group V elements other than N (nitrogen) in the chemical formula above, various elements added to control various properties such as the conductivity type and the like, and various elements included in unintentionally.

In this specification, being “electrically connected” includes not only the case of being connected in direct contact, but also the case of being connected via another conductive member, etc.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a support body including a first surface;
a first conductive part, a direction from the first surface toward the first conductive part being along a first direction perpendicular to the first surface;
a second conductive part separated from the first conductive part in a second direction along the first surface;
a semiconductor layer including a first end surface, a second end surface, a counter region, and a first semiconductor region, the first end surface being positioned between the first conductive part and the second conductive part, the second end surface being positioned between the first end surface and the support body, the first semiconductor region being of a first conductivity type, the counter region being positioned between the second conductive part and the first semiconductor region and facing a portion of the second conductive part;
a third conductive part separated from the counter region and a portion of the second conductive part in a third direction, the third direction crossing the second direction and being along the first surface; and
a fourth conductive part separated from the first semiconductor region in the third direction,
the first semiconductor region including
a first upper end region including a portion of the first end surface,
a first lower end region including a portion of the second end surface, and
a first intermediate region positioned between the first upper end region and the first lower end region,
a first-conductivity-type impurity concentration in the first upper end region being greater than a first-conductivity-type impurity concentration in the first intermediate region,
a first-conductivity-type impurity concentration in the first lower end region being greater than the first-conductivity-type impurity concentration in the first intermediate region.

2. The device according to claim 1, wherein
the counter region is of the first conductivity type and has a Schottky contact with the portion of the second conductive part.

3. The device according to claim 1, wherein
the counter region is of a second conductivity type.

4. The device according to claim 1, further comprising:
a first insulating layer contacting the first end surface, and
a second insulating layer contacting the second end surface.

5. The device according to claim 4, wherein
the first insulating layer contacts one end in the first direction of the fourth conductive part, and
the second insulating layer contacts another end in the first direction of the fourth conductive part.

6. The device according to claim 4, wherein
a thickness of the first insulating layer is not less than 250 nm and not more than 1,250 nm, and
a thickness of the second insulating layer is not less than 250 nm and not more than 1,250 nm.

7. The device according to claim 1, wherein
the first-conductivity-type impurity concentration in one of the first upper end region or the first lower end region is greater than the first-conductivity-type impurity concentration in the other of the first upper end region or the first lower end region.

8. The device according to claim 7, further comprising:
a first conductive layer electrically connected with the first conductive part,
the other of the first upper end region or the first lower end region being positioned between the first conductive layer and the one of the first upper end region or the first lower end region.

9. The device according to claim 4, wherein
the first lower end region is positioned between the first insulating layer and the second insulating layer,
the first upper end region is positioned between the first lower end region and the first insulating layer, and
a thickness of one of the first insulating layer or the second insulating layer is less than a thickness of the other of the first insulating layer or the second insulating layer.

10. The device according to claim 9, further comprising:
a first conductive layer electrically connected with the first conductive part,
the other of the first insulating layer or the second insulating layer being positioned between the first conductive layer and the one of the first insulating layer or the second insulating layer.

11. The device according to claim 8, wherein
the second end surface is positioned between the first end surface and the first conductive layer.

12. The device according to claim 8, further comprising:
a second conductive layer electrically connected with the second conductive part,
the semiconductor layer being positioned between the first conductive layer and the second conductive layer.

13. The device according to claim 1, wherein
the semiconductor layer includes a second semiconductor region separated from the fourth conductive part in the second direction and positioned between the fourth conductive part and the first conductive part, the second semiconductor region being of the first conductivity type,
the second semiconductor region includes
a second upper end region including a portion of the first end surface,
a second lower end region including a portion of the second end surface, and
a second intermediate region positioned between the second upper end region and the second lower end region,
a first-conductivity-type impurity concentration in the second upper end region is greater than a first-conductivity-type impurity concentration in the second intermediate region, and
a first-conductivity-type impurity concentration in the second lower end region is greater than the first-conductivity-type impurity concentration in the second intermediate region.

14. The device according to claim 13, wherein
the semiconductor layer includes a third semiconductor region positioned between the first semiconductor region and the first conductive part in the second direction, the third semiconductor region being of the first conductivity type,
a direction from the second semiconductor region toward the third semiconductor region is along the third direction,
the third semiconductor region includes
a third upper end region including a portion of the first end surface,
a third lower end region including a portion of the second end surface, and
a third intermediate region positioned between the third upper end region and the third lower end region,
a first-conductivity-type impurity concentration in the third upper end region is greater than a first-conductivity-type impurity concentration in the third intermediate region, and
a first-conductivity-type impurity concentration in the third lower end region is greater than the first-conductivity-type impurity concentration in the third intermediate region.

15. The device according to claim 1, wherein
the fourth conductive part is electrically connected with the second conductive part.

16. The device according to claim 1, wherein
a thickness of the first upper end region is not less than 100 nm and not more than 1,000 nm,
a thickness of the first lower end region is not less than 100 nm and not more than 1,000 nm,
the thickness of the first upper end region is less than a thickness of the first intermediate region, and
the thickness of the first lower end region is less than the thickness of the first intermediate region.

17. The device according to claim 16, wherein
a first-conductivity-type impurity amount included in the first upper end region is greater than a first-conductivity-type impurity amount included in the first intermediate region.

18. The device according to claim 17, wherein
a difference between the first-conductivity-type impurity amount included in the first upper end region and the first-conductivity-type impurity amount included in the first intermediate region is not less than 5×10¹⁰ atoms/cm² and not more than 1.5×10¹¹ atoms/cm² per unit area in a plane perpendicular to the first direction.

19. The device according to claim 1, wherein
the first-conductivity-type impurity concentration in the first intermediate region is not less than 1×10¹⁶ atoms/cm³ and not more than 5×10¹⁶ atoms/cm³, and
the first-conductivity-type impurity concentration in the first upper end region is not less than 1.3×10¹⁶ atoms/cm³ and not more than 6.5×10¹⁶ atoms/cm³.

20. The device according to claim 1, further comprising:
an insulating part including
a first insulating region located between the third conductive part and the counter region, and
a second insulating region located between the fourth conductive part and the first semiconductor region.
